(19) United States
(12) Patent Application Publication
(10) Pub. No.: US 2026/0239973 A1
(43) Pub. Date: Aug. 13, 2026

(54) SYSTEM AND METHODS FOR MULTI-PHASE SEMICONDUCTOR PACKAGE COOLING

(71) Applicant: Samsung Electronics Co., Ltd., Suwon-si (KR)

(72) Inventors: Hongxia GAO, Santa Clara, CA (US); WooPoung KIM, San Jose, CA (US)

(21) Appl. No.: 19/315,469

(22) Filed: Aug. 29, 2025

Related U.S. Application Data
(60) Provisional application No. 63/757,302, filed on Feb. 11, 2025.

(51) Int. Cl. H01L 23/44; H01L 23/427

(52) U.S. Cl. CPC H10W 40/30; H10W 40/73

(57) ABSTRACT

Disclosed herein are methods, devices and systems including a supporting board and a first cooling structure on the supporting board, the first cooling structure including a first high-power density package immersed within a first dielectric fluid which is thermally coupled to the first high-density package, and the first high-density package may be communicatively coupled to the supporting board. A first vapor collector with a converging-diverging shape within the first cooling structure passively circulates the first dielectric fluid in a closed loop within the first cooling structure. The first dielectric fluid may have a first liquid phase and a first vapor phase within the first cooling structure, and the first dielectric fluid circulating within a closed loop within the first cooling structure may include the first liquid phase transitioning to the first vapor phase and the first vapor phase transitioning to the first liquid phase.

### CROSS-REFERENCE TO RELATED APPLICATION

This application claims the priority benefit under 35 U.S.C. § 119(e) of U.S. Provisional Patent Application Ser. No. 63/757,302 filed on Feb. 11, 2025, the disclosure of which is incorporated herein by reference in its entirety.

### TECHNICAL FIELD

The subject matter disclosed herein relates to microelectronics and integrated circuit (IC) structures. More particularly, the subject matter disclosed herein relates to a semiconductor structure involving a heat transfer mechanism.

### BACKGROUND

Semiconductor devices may be created using complex structures made up of sets of smaller components, which may be referred to as packages. Packaging describes the general method for connecting and integrating multiple computational components together in an integrated unit and may involve multiple different types of integrated circuits on multiple substrates, which may combine into a single unit. Packaging may also describe a method for which multiple computational components within a single unit are protected by the use of various techniques to provide thermal, physical and electrical protection. However, cooling structure components face a number of challenges. For example, to increase capacity in computer such as a server, the ability to transfer heat needs to be increased. This may present challenges in the fabrication process.

It is further noted that background concepts discussed herein are for informational purposes only and are not intended to limit the present disclosure, nor should the background or field described be intended to limit the disclosure herein to a particular use or concept.

### SUMMARY

An example embodiment provides a device with a supporting board and a first cooling structure on the supporting board. The first cooling structure may include a first high-power density package immersed within a first dielectric fluid, the first dielectric fluid may be thermally coupled to the first high-density package, and the first high-density package may be communicatively coupled to the supporting board. A first vapor collector with a converging-diverging shape may be within the first cooling structure. The first dielectric fluid may circulate in a closed loop within the first cooling structure. The first dielectric fluid may have a first liquid phase and a first vapor phase within the first cooling structure, and the first dielectric fluid circulating within a closed loop within the first cooling structure may include the first liquid phase transitioning to the first vapor phase and the first vapor phase transitioning to the first liquid phase. A second cooling structure may be on the supporting board, and the second cooling structure may have a second high-power density package immersed within a second dielectric fluid, the second dielectric fluid may be thermally coupled to the second high-density package, and the second high-density package may be communicatively coupled to the supporting board. A second vapor collector with a converging-diverging shape may be within the second cooling structure. The first high-density package may include at least one of a memory device and a processing device. The first cooling structure may have a fixed volume that the first dielectric fluid circulates within. The first dielectric fluid may passively circulate within a closed loop within the first cooling structure. The first vapor collector may include a fan to actively circulate the first dielectric fluid in a closed loop within the first cooling structure

An example embodiment provides a device with a supporting board and a first cooling structure on the supporting board. The first cooling board may include a first high-power density immersed within a first dielectric fluid, the first dielectric fluid thermally coupled to the first high-power density package, the first high-power density package communicatively coupled to the supporting board, and a first vapor collector having a converging-diverging shape to passively circulate the first dielectric fluid. The first cooling structure may provide a nucleation site for the first dielectric fluid to transition from vapor phase to liquid phase. The first cooling structure may have a fixed volume and the first dielectric fluid may circulate in a closed loop within the cooling structure. At least one cooling device may be mounted on an exterior of the first cooling structure, and the at least one cooling device may include one or more of a thermoelectric cooler, a cold plate, a heat exchanger, a radiative fin and a heat sink. The first high-power density package may include at least one of a memory device and a processing device. A second cooling structure may be on the supporting board, and the second cooling structure may have a second high-power density package immersed within a second dielectric fluid, the second dielectric fluid may be thermally coupled to the second high-density package, and the second high-density package may be communicatively coupled to the supporting board. A second vapor collector with a converging-diverging shape may be within the second cooling structure and passively circulate the second dielectric fluid. The second cooling structure may have a nucleation site for the second dielectric fluid to transition from vapor phase to liquid phase. The first vapor collector may include a fan to actively circulate the first dielectric fluid in a closed loop within the first cooling structure.

An example embodiment provides a system including a supporting board with a first cooling structure and a second cooling structure on the supporting board. The first cooling structure may include a first high-power density package immersed within a first dielectric fluid, the first dielectric fluid may be thermally coupled to the first high-density package, and the first high-density package may be communicatively coupled to the supporting board. A first vapor collector with a converging-diverging shape may be within the first cooling structure. The second cooling structure may include a second high-power density package immersed within a second dielectric fluid, the second dielectric fluid may be thermally coupled to the second high-density package, and second first high-density package may be communicatively coupled to the supporting board. A second vapor collector with a converging-diverging shape may be within the second cooling structure. The first vapor collector may passively circulate the first dielectric fluid, and the second vapor collector may passively circulate the second dielectric fluid. The first high-power density package may include at least one of a memory device and a processing device. The supporting board, the first cooling structure, and the second cooling structure may be immersed within a liquid coolant in an immersion bath. The first cooling structure may have a first boiling enhancement surface providing a first nucleation site for the first dielectric fluid to condense. The second cooling structure may have a second boiling enhancement surface providing a second nucleation site for the second dielectric fluid to condense. The first vapor collector may include a first fan to actively circulate the first dielectric fluid in a closed loop within the first cooling structure. The second vapor collector may include a second fan to actively circulate the second dielectric fluid in a closed loop within the second cooling structure. At least one first cooling device may be mounted on an exterior of the first cooling structure, and the at least one first cooling device may include one or more of a thermoelectric cooler, a cold plate, a heat exchanger, a radiative fin and a heat sink. At least one second cooling device may be mounted on an exterior of the second cooling structure, and the at least one second cooling device may include one or more of a thermoelectric cooler, a cold plate, a heat exchanger, a radiative fin and a heat sink. The first cooling structure may have a fixed volume and the second cooling structure may have a fixed volume.

### BRIEF DESCRIPTION OF THE DRAWING

In the following section, the aspects of the subject matter disclosed herein will be described with reference to example embodiments illustrated in the figures, in which:

FIG. 1 depicts a cross-sectional view of a semiconductor structure of two passive cooling structures for high-power package devices on a shared board according to various embodiments of the subject matter disclosed herein;

FIG. 2 depicts a cross-sectional view of a semiconductor structure of two passive cooling structures for high-power package devices on a shared board circulating vapor according to various embodiments of the subject matter disclosed herein;

FIG. 3 depicts a perspective view of a cooling surface structure according to various embodiments of the subject matter disclosed herein;

FIG. 4 depicts a cross-sectional view of a semiconductor structure of two passive cooling structures for high-power package devices on a shared board circulating vapor with additional cooling according to various embodiments of the subject matter disclosed herein;

FIG. 5 depicts a cross-sectional view of a semiconductor structure of two passive cooling structures for high-power package devices on a shared board within an immersion bath according to various embodiments of the subject matter disclosed herein;

FIG. 6 depicts a cross-sectional view of a semiconductor structure of two passive cooling structures for high-power package devices on a shared board circulating vapor using a fan according to various embodiments of the subject matter disclosed herein;

FIG. 7 depicts a cross-sectional view of a semiconductor structure of two passive cooling structures for high-power package devices on a shared board with and without supporters according to various embodiments of the subject matter disclosed herein;

FIG. 8 depicts a cross-sectional view of a semiconductor structure of two passive cooling structures for high-power package devices on a shared board circulating vapor with and without supporters according to various embodiments of the subject matter disclosed herein; and

FIG. 9 depicts a flow chart demonstrating a method of creating a cooling structure according to various embodiments of the subject matter disclosed herein.

### DETAILED DESCRIPTION

In the following detailed description, numerous specific details are set forth in order to provide a thorough understanding of the disclosure. It will be understood, however, by those skilled in the art that the disclosed aspects may be practiced without these specific details. In other instances, well-known methods, procedures, components and circuits have not been described in detail to not obscure the subject matter disclosed herein.

Reference throughout this specification to “one embodiment” or “an embodiment” means that a particular feature, structure, or characteristic described in connection with the embodiment may be included in at least one embodiment disclosed herein. Thus, the appearances of the phrases “in one embodiment” or “in an embodiment” or “according to one embodiment” (or other phrases having similar import) in various places throughout this specification may not necessarily all be referring to the same embodiment. Furthermore, the particular features, structures or characteristics may be combined in any suitable manner in one or more embodiments. In this regard, as used herein, the word “exemplary” means “serving as an example, instance, or illustration.” Any embodiment described herein as “exemplary” is not to be construed as necessarily preferred or advantageous over other embodiments. Additionally, the particular features, structures, or characteristics may be combined in any suitable manner in one or more embodiments. Also, depending on the context of discussion herein, a singular term may include the corresponding plural forms, and a plural term may include the corresponding singular form. Similarly, a hyphenated term (e.g., “two-dimensional,” “pre-determined,” etc.) may be occasionally interchangeably used with a corresponding non-hyphenated version (e.g., “two dimensional,” “predetermined, etc.), and a capitalized entry (e.g., “Counter Clockwise,” “Three-Dimensional,” etc.) may be interchangeably used with a corresponding non-capitalized version (e.g., “counter clockwise,” “three-dimensional,” etc.). Such occasional interchangeable uses shall not be considered inconsistent with each other.

Also, depending on the context of discussion herein, a singular term may include the corresponding plural forms, and a plural term may include the corresponding singular form. It is further noted that various figures (including component diagrams) shown and discussed herein are for illustrative purpose only and are not drawn to scale. For example, the dimensions of some of the elements may be exaggerated relative to other elements for clarity. Further, if considered appropriate, reference numerals have been repeated among the figures to indicate corresponding and/or analogous elements.

The terminology used herein is for the purpose of describing some example embodiments only and is not intended to be limiting of the claimed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being on, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

The terms “first,” “second,” etc., as used herein, are used as labels for nouns that they precede, and do not imply any type of ordering (e.g., spatial, temporal, logical, etc.) unless explicitly defined as such. Furthermore, the same reference numerals may be used across two or more figures to refer to parts, components, blocks, circuits, units, or modules having the same or similar functionality. Such usage is, however, for simplicity of illustration and ease of discussion only; it does not imply that the construction or architectural details of such components or units are the same across all embodiments or such commonly-referenced parts/modules are the only way to implement some of the example embodiments disclosed herein.

The term “surround” (as in “a first object surrounds a second object”) as used herein describes the first object enclosing or is formed around or over the second object, or the first object accommodates, conforms, follows, aligns, or follows the path of the second object.

Unless otherwise defined, all terms (including technical and scientific terms) used herein have the same meaning as commonly understood by one of ordinary skill in the art to which this subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, compute devices may refer to a wide variety of integrated circuits using electrical components. In some embodiments, compute devices may include central processing units (CPUs), logic chips, memory such as static random-access memory (SRAM), dynamic random-access memory (DRAM), synchronous dynamic random-access memory (SDRAM), double data rate DRAM or DDR DRAM, application processors (AP), auxiliary processing units (XPUs), graphical processing units (GPUs), artificial intelligence (AI) chips, high bandwidth memory (HBM), and other application-specific integrated circuits (ASIC). In some embodiments, a combination of circuits may be present on a substrate. In some embodiments, compute devices may be referred to in terms such as microchips, microcontrollers, silicon chips. As used herein, an XPU may refer to an auxiliary processing unit designed to perform specialized or dedicated processing optimized for conducting specific tasks more efficiently than a general processing unit such as a CPU, and may be also referred to as a data processing unit (DPU), infrastructure processing unit (IPU), function accelerator card (FAC), or network attached processing unit (NAPU).

As used herein substrates may refer to a variety of materials and structures, including wafers using silicon, wafers using silicon on an insulator (SOI) such as glass, wafers of other semiconductor materials such as germanium, as well as other semiconductor materials on an insulator. In some embodiments, a substrate may include an organic material. In some embodiments, the substrates may be referred to as wafers, dies, and chips alone or in combination. Bonding substrates may be thus known in some embodiments as die-to-die (D2D) bonding, wafer-to-wafer bonding (W2W) or die-to-wafer bonding (D2W). In some embodiments, a packaged chip may contain multiple substrates.

As used herein packaging refers to a process of forming interconnections between substrates. In some embodiments, the interconnections may be between direct surfaces and involve W2W, D2D, and D2W bonding. In other embodiments, techniques including wire bonding and other forms of indirect bonding may be performed alone or in combination with W2W, D2D, and D2W bonding. In some embodiments, circuits may be bonded directly facing each other, while in other embodiments a flip-chip bonding may be used. In some embodiments, interconnections may be made between substrates on a front or circuit side of the substrate.

As used herein, dielectric fluids refer to dielectric materials in liquid and/or vapor form. Dielectric materials are materials that have a low relative permittivity or a low dielectric constant, and thus function as an electrically non-conductive material. Dielectric fluids may maintain that state in liquid or vapor form. A multi-phase dielectric fluid may act as a dielectric material in both liquid and vapor form. Example dielectric fluids may include mineral oils, synthetic esters, silicone fluids, fluorinated liquids, hydrocarbon oils, as well as any other suitable fluid, as this list is not intended to be exhaustive.

Disclosed herein are various embodiments of devices, systems and methods related to immersion cooling of a heat producing computing package using a multi-phase dielectric fluid. A heat producing computing package may include a number of compute devices and other integrated circuits on a shared substrate and may include a stack of compute devices in a form such as HBM, a GPU, as well as three-dimensional memory and other complex packaged semiconductors in a small volume. Such a heat producing package may be suitable for high complexity computing purposes such as AI, graphical rendering, large scale computational modeling, etc. where density of compute devices and supporting circuits provide a performance increase, for example, by reducing distances for signals to travel between memory units and processing units. A denser packaging structure of components such as processing units, however, may produce a larger amount of heat across a smaller surface area, which may provide a decrease in the performance of denser packaging. Immersion cooling with a multi-phase dielectric fluid provides a means of cooling high-density computing packages, enabling increased performance.

A dielectric fluid may be any suitable fluid or mix of fluids having a high thermal conductivity, good compatibility with the materials of the high-power density packages and provides electrical insulation between the high-power density package and the surrounding environment. For example, a dielectric fluid may include one or more mineral oils, synthetic esters, silicone fluids, fluorinated liquids, hydrocarbon oils, as well as any other suitable fluid. The dielectric fluid may provide increased thermal conductivity compared to the thermal conductivity of air or vacuum. The dielectric fluid may have good material compatibility with the materials of the high-power density package such as with respect to preventing corrosion, avoiding dissolving of packaging materials such as molding compounds, avoiding damage of the packaging materials, as well as avoiding buildup of deposits on the packaging by the dielectric fluid, or reactions with either the packaging material or materials the dielectric fluid may encounter within a cooling loop. The dielectric fluid may take the form of a dielectric material and act as an electric insulator such that an electrical current from the high-power density package is not transmitted via the dielectric fluid to a surrounding environment.

A high-power density package is a package having one or more electrical components including compute devices including processing devices and memory devices, as well as supporting circuitry, and may take the form of a chiplet, individual IC chips such as CPUs, GPUs, NPUs, and advanced packages such as HBM, as well as three-dimensional structures such device stacks where a combination of devices may be formed into a larger stack of devices. A package may be a high-power density package when the power consumption of the package exceeds a threshold such that the one or more component devices may exceed their operating temperature when running on a standard board. The threshold may vary by device and package, and a package may be limited by the sensitivity of the lowest device on the package. For example, in some embodiments, a high-power density package may produce 1 W, 10 W, 100 W, 1 kW, 2 kW or more of heat, although in other embodiments the threshold for a high-power density package may be lower or higher.

The multi-phase dielectric fluid may surround the high-power density package within a cooling structure. The cooling structure may be a three-dimensional solid structure, such as a box, cube, prism, cylinder, or other suitable three-dimensional shape. The cooling structure may also be referred to as a cooling box, although it should be understood to the cooling structure is not limited to the shape of a box. The cooling structure may be sealed such that the multi-phase dielectric fluid within the cooling structure may stay within the cooling structure and avoid either leaking from the cooling structure or being circulated through an external system. The cooling structure may have a bottom side, which may rest on a connector structure, the connector structure providing routing for power and communication signals between the high-power density package and a supporting board. The supporting board may be a printed circuit board (PCB) or take the form of a card such as a graphics card and may host multiple high-power density packages in individual cooling structures which may route power and communications signals via the supporting board. The cooling structure may have a fixed volume, such that the volume of the cooling structure remains approximately constant over the operating range.

The high-power density package may be mounted on a supporter. The supporter may provide both physical support for the high-power density package, as well as provide one or more coupling channels for power and communication signals between the high-power density package and the connector. The supporter may take the form of any suitable structure and may include one or more structural supports as well as one or more vias to allow the multi-phase dielectric fluid to contact the high-power density package from below.

The multi-phase dielectric fluid may include a vapor phase and a liquid phase within the cooling structure separated by a phase boundary, which may be the surface of the liquid phase. The high-power density package may be immersed within the liquid phase of the multi-phase dielectric fluid, such that the top and sides may be fully in contact with the liquid phase, and a portion of the bottom of the high-power density package may contact the liquid phase depending on the structure of the supporter.

As the high-power density package may have most of its surface area in contact with the liquid phase of the multi-phase dielectric fluid, heat produced by the high-power density package may be transferred to the liquid phase of the multi-phase dielectric fluid. The multi-phase dielectric fluid may have a higher specific heat capacity than air or the material forming the supporting board. The dielectric fluid may also have a higher thermal conductivity than air or the material forming the supporting board. As such, the liquid phase of multi-phase dielectric fluid may allow heat to transfer away from the high-power density package at a greater rate than conductive contact with the supporting board or the air alone. Additionally, as heat may be transferred from the high-power density package to the liquid phase, the liquid phase may heat up until reaching the boiling point of the multi-phase dielectric fluid. Upon the liquid phase being heated to the boiling point of the multi-phase dielectric fluid, the liquid phase will reach a temperature plateau, as additional heat added to the liquid phase from the high-power density package may be consumed by the latent heat of the phase change of the multi-phase dielectric fluid from liquid phase to vapor phase.

The cooling structure may allow the multi-phase dielectric fluid to transfer heat from both the liquid phase and the vapor phase to the surrounding environment. The cooling structure may be made of a thermally conductive material such as a metal like copper, various alloys of steel, gold, silver and aluminum, as well as other thermally conductive materials such as boron arsenide, diamond, ceramics like aluminum nitride or silicon nitride, or any other suitable material, as well as combinations thereof. The cooling structure may directly conduct heat to air surrounding the cooling structure. The surfaces of the cooling structure may function as a heat spreader. The cooling structure will have a larger surface area than the high-power density package, thus may allow a greater transfer of heat from the high-power density package compared to direct transfer. The cooling structure may have a cooling surface on an upper surface within the cooling structure. The cooling surface may, for example, be made of a material having a relatively high surface area, such as a microstructured or nanostructured foam made from a thermally conductive material, such as copper, as well as ceramics, doped carbon, or other suitable materials. The cooling surface may also be referred to as a boiling enhancement surface. The surfaces of the cooling structure may each function as a heat spreader, transferring heat produced within the high-power density package to the cooling structure surfaces where the increased surface area may transfer heat away to a surrounding environment quicker than heat may be produced.

In addition, the heat transfer may be further increased by mounting additional cooling structures on the surfaces of the cooling structure, including the surface opposite the cooling surface. For example, one or more of thermoelectric cooling plates using the Peltier effect, liquid cooling plates, heat exchangers, heat sinks, radiative fins, fans, or any other suitable cooling structure, may be formed on one or more exterior surfaces of the cooling structure. Such a listing of elements is not intended to be exhaustive, and in other embodiments, any known type of cooling device may be used. In some embodiments, the cooling structure may also be submerged within an additional cooling bath, such as an open immersion bath, which additional packages and components may share. In further embodiments, multiple cooling structures may be in a nesting configuration where multiple packages, each with an individual cooling structure, may be within a larger immersion cooling bath, which may in turn be within an even larger immersion cooling bath.

Furthermore, the cooling structure may use passive structures within to provide thermal regulation. A collector may be formed in the vapor phase region of the cooling structure. The collector may have a concave surface rounded down toward the liquid phase region with a nozzle at the apex of the collector. The nozzle may have a converging-diverging shape to form a de Laval nozzle, also referred to as a laval nozzle, a CD nozzle, a con-di nozzle or a convergent-divergent nozzle. The converging-diverging nozzle may be formed such that the inlet of the converging-diverging nozzle may be oriented toward the liquid phase, while the outlet may be oriented toward the cooling surface. The converging-diverging nozzle can be a form of a converging-diverging tube with a pinched middle between the inlet and the outlet operating using the Venturi effect. The center of the converging-diverging nozzle may also be referred to a choke or pinch. Vapor entering the converging-diverging inlet transfers a portion of its thermal energy to kinetic energy, as the exhaust velocity of the vapor may be greater than the inlet velocity. As such, the collector may provide passive cooling to the vapor, with the collector extending across much of the cooling structure such that rising vapor from the boiling surface may be routed via the converging-diverging nozzle. The faster, but cooler vapor exiting the converging-diverging nozzle may contact the cooling surface. As the cooling surface may be constructed to have a relatively large contact surface, the cooling surface provides a nucleation surface for droplets of the multi-phase dielectric fluid to condense from vapor phase to liquid phase. In some embodiments, the cooling surface may be referred to as a nucleation surface, nucleation site, or a boiling enhancement surface. Condensed droplets may then fall from the cooling surface to the upper side of the collector and drip around the collector rim back to the liquid phase below. The cooling structure with multi-phase dielectric fluid thus may allow for heat to be transferred easily from a high-power density package to the fluid, which may maintain an equilibrium passively at the boiling point of the multi-phase dielectric fluid, while the multi-phase dielectric fluid may cycle between liquid and vapor. The cooling structure may, in some embodiments, provide a forced circulation (e.g., installing a fan at an inlet to the nozzle to force the vapor phase through the nozzle at a higher velocity).

The immersion cooling structure using multi-phase dielectric fluid may provide a low energy or passive cooling for high-density packaging while maintaining efficient thermal transfer. The dielectric fluid may transfer heat from the high-power density package to the surface of the cooling structure, where an increased surface area may reduce the heat flux of the cooling structure compared to the high-power density package. Furthermore, the dielectric fluid may have an increased thermal conductivity compared to the supporting board or components the high-power density package may contact, providing thermal pathway for heat to transfer to the dielectric fluid and away from the board. In addition, the dielectric fluid may have a higher heat capacity than the supporting board or components the high-power density package is in contact with, such that heat from the high-power density package is transferred into the dielectric fluid at a higher rate due to the increased heat capacity of the dielectric fluid acting as a thermal sink. The heat capacity may be even further increased when the dielectric fluid has multiple phases within the operating zone, as enthalpy of vaporization may further increase the relative heat capacity of the dielectric fluid. As such, heat may be more quickly transferred from the individual packages to the cooling structures while providing a thermal sink where additional thermal energy is consumed by phase transitions, keeping the high-power density packages at the boiling temperature of the dielectric fluid.

Additionally, by providing closed cycle cooling on the package level, the amount of dielectric fluid may be minimized for each cooling structure, allowing for more expensive but effective coolants to be used. Furthermore, the package level cooling may be combined with additional cooling methods to further cool at the board, computer, rack and datacenter level scale. As a result, the amount of energy required to cool the high-power density package may be low or even zero. As such, the power usage efficiency or PUE of data center using high-power density packages within cooling structures disclosed herein may be approximately 1.0 when no additional cooling mechanisms are provided, or in the range of 1.01 to 1.03 when additional cooling plates, thermoelectric coolers, or similar means are used to provide additional cooling beyond the passive cooling.

The cooling structures may be partially assembled with a top and side surfaces first joined together, such as via welding or mechanical fasteners. The high-power density packages may be separately assembled from individual components including integrated circuits. The vapor collectors and cooling surface may be formed directly as part of the side or top of the cooling structure or may be joined to the surfaces during assembly. The high-power density packages are mounted on the bottom surfaces of the cooling structures, either directly or on a supporter. The top, side, and bottom sides of the cooling structures are then assembled together. The assembled cooling structures may then be mounted to connectors on the supporting board prior to filling the cooling structures with the dielectric fluid.

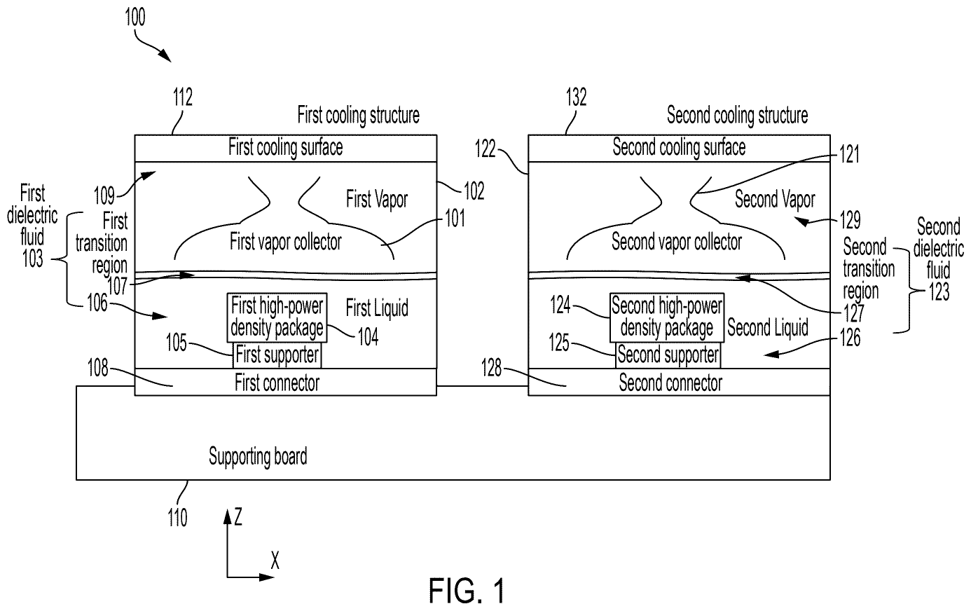

FIG. 1 depicts a cross-sectional view of an example embodiment of a first cooling architecture 100. One or more cooling structures, including a first cooling structure 102 and a second cooling structure 122 may be mounted on a supporting board 110. The supporting board 110 may take the form of a PCB, an interposer, a substrate, or take the form of a card such as a graphics card. The supporting board 110 may form a portion of a larger computer, which may in turn be incorporated into additional structures such as a server, server rack, and data center. The supporting board 110. The first cooling structure 102 contains a first high-power density package 104 and the second cooling structure 122 contains a second high-power density package 124. The first high-power density package 104 and the second high-power density package 124 may include one or more compute devices as well as supporting circuitry, and take the form of a chiplet, individual IC chips such as CPUs, GPUs, NPUs, and advanced packages such as HBM, as well as three-dimensional structures such device stacks and vertically stacked DRAM (VSDRAM). As used herein, a device stack or stack of devices may refer to a combination of memory and supporting circuit architecture, for example, chiplets and dies containing individual memory elements, supporting processing units, input output (I/O) circuitry, and other forms of integrated chips. As used herein, a chiplet may refer to an integrated circuit having a well-defined functionality, such as a microprocessor, a memory device, or other computational function; with a chiplet enabling a modular design with multiple chiplets able to be combined with a larger package, sharing a substrate or interposer to form a larger device. A core may refer to a single unit of a multicore device where multiple devices form a larger device, with each device able to function independently to enable multiple streams of operations. In some embodiments, a core may take the form of a chiplet, or a chiplet may take the form of a core. However, in other embodiments, a chiplet may take the form of any other suitable integrated circuit. As used herein, high bandwidth memory, or HBM, may refer to a chip structure including one or more HBM modules. In some embodiments, the HBM may be manufactured by an advanced silicon node process.

The first cooling structure 102 may contain a first dielectric fluid 103 and the second cooling structure 122 may contain a second dielectric fluid 123. The first dielectric fluid 103 and the second dielectric fluid 123 may have a low relative permittivity or dielectric constant, and thus function as an electrically non-conductive material, while having sufficient heat capacity to provide relatively good thermal conductivity. Example dielectric fluids may include mineral oils, synthetic esters, silicone fluids, fluorinated liquids, hydrocarbon oils, as well as any other suitable fluid, as this list is not intended to be exhaustive. In addition, the first dielectric fluid 103 and the second dielectric fluid 123 may be multi-phase dielectric fluids, including both a liquid phase and a vapor phase, with both phases functioning as dielectric materials providing electrical non-conductance and thermal conductivity. The first dielectric fluid 103 may include a first dielectric liquid 106, a first dielectric vapor 109, and a first transition region 107 where the first dielectric liquid 106 may transform to the first dielectric vapor 109. The second dielectric fluid 123 may include a second dielectric liquid 126, a second dielectric vapor 129, and a second transition region 127 where the second dielectric liquid 126 may transform to the second dielectric vapor 129. The first high-power density package 104 may be immersed in the first dielectric liquid 106 while the second high-power density package 124 may be immersed in the second dielectric liquid 126.

The first high-power density package 104 may be mounted on a first supporter 105, while the second high-power density package 124 may be mounted on a second supporter 125. The first supporter 105 and the second supporter 125 may take the form of a physically supportive structure allowing dielectric liquid to contact at least a portion of the first high-power density package 104 or the second high-power density package 124 and provide a physical connection to a corresponding connector on the supporting board 110. The first supporter 105 and the second supporter 125 also may contain one or more connections to allow the supporting board 110 to couple power and communications signals to the first high-power density package 104 or the second high-power density package 124. The first supporter 105 and the second supporter 125 may be configured in a variety of ways, and may be a solid shape such as a cube, structure or prism mounted directly to the bottom of the first cooling structure 102 or the second cooling structure 122, as well as may be formed from one or more separate elements, such as legs. In some embodiments, the first supporter 105 and the second supporter 125 may allow the first dielectric fluid 103 or the second dielectric fluid 123 to travel between the high-power density packages and the bottom of the cooling structures, while in others, the first supporter 105 and the second supporter 125 may be sized such that the space between the high-power density packages and the bottom of the cooling structures may be occupied.

The first supporter 105 may couple directly to a first connector 108 and the second supporter 125 may couple directly to a second connector 128. The first connector 108 and the second connector 128 may provide a connection for power and communications signals between the supporting board 110 and the first high-power density package 104 or the second high-power density package 124, which may be routed via the first supporter 105 or the second supporter 125. The first connector 108 and the second connector 128 may take many forms, including a redistribution layer (RDL), which may include one or more individual layers including one or more conductive materials, such as a series of pads, bumps, vias, through-vias, traces, and other forms of connection for redistributing signals across the layer. The first connector 108 and the second connector 128 may allow for signals to travel both laterally and vertically between the first high-power density package 104 or the second high-power density package 124 and the supporting board 110. In some embodiments, the first connector 108 and the second connector 128 may form a portion of the bottom of the first cooling structure 102 or the second cooling structure 122, while in other embodiments, the first supporter 105 or the second supporter 125 may extend through a portion of the first cooling structure 102 or the second cooling structure 122 to couple to the first connector 108 and the second connector 128.

The first cooling structure 102 and the second cooling structure 122 may take the form of a structure, prism, or similar shapes, including a top, a bottom and sidewalls extending between. In the example embodiments discussed herein, there may be four sidewalls, but in some embodiments, the number of sidewalls may be larger or smaller, based on the desired geometry. The first cooling structure 102 and the second cooling structure 122 may be formed from a material with relatively good thermal conductivity, such as a metal like copper, various alloys of steel, gold, silver and aluminum, as well as other thermally conductive materials such as boron arsenide, diamond, ceramics like aluminum nitride or silicon nitride, or any other suitable material, as well as combinations thereof. With the exception of a portion of the bottom for allowing the first connector 108 and the second connector 128 to couple to the first supporter 105 or the second supporter 125, the first cooling structure 102 and the second cooling structure 122 may be sealed such that the first dielectric fluid 103 and the second dielectric fluid 123 may be sealed respectfully within the first cooling structure 102 and the second cooling structure 122. As such, the first cooling structure 102 and the second cooling structure 122 may form a closed loop cooling system, where the first dielectric fluid 103 cycles purely within the first cooling structure 102 and the second dielectric fluid 123 may cycle purely within the second cooling structure 122. The surfaces of the first cooling structure 102 and the second cooling structure 122 may each function as a heat spreader.

The first cooling structure 102 and the second cooling structure 122, being sealed, may have heat produced by the first high-power density package 104 or the second high-power density package 124 absorbed by the first dielectric liquid 106 or the second dielectric liquid 126. As the first dielectric fluid 103 and the second dielectric fluid 123 may be chosen to have relatively good thermal conductivity, heat may be efficiently transferred to the first dielectric liquid 106 or the second dielectric liquid 126. As the first dielectric liquid 106 heats up, the first dielectric liquid 106 may begin to boil, forming the first transition region 107 where the first dielectric fluid 103 may transition from the first dielectric liquid 106 to the first dielectric vapor 109. As the second dielectric liquid 126 heats up, the second dielectric liquid 126 may begin to boil, forming the second transition region 127 where the second dielectric fluid 123 may transition from the second dielectric liquid 126 to the second dielectric vapor 129. The first dielectric fluid 103 and the second dielectric fluid 123 may be chosen, at least in part, such that the first high-power density package 104 or the second high-power density package 124 may operate efficiently at the boiling point of the first dielectric fluid 103 or the second dielectric fluid 123. At the boiling point, additional thermal energy produced by the first high-power density package 104 or the second high-power density package 124, which may be transmitted to the first dielectric fluid 103 or the second dielectric fluid 123, may be consumed by the phase transition between the liquid and vapor phases, and such may allow the temperature of the high-power density package to reach a stable state.

Furthermore, the first cooling structure 102 and the second cooling structure 122 may have a larger surface area than the first high-power density package 104 or the second high-power density package 124 as the first cooling structure 102 or the second cooling structure 122 contain the first high-power density package 104 or the second high-power density package 124 within along with the additional components such as the first dielectric fluid 103 or the second dielectric fluid 123. The larger surface area may allow the first cooling structure 102 and the second cooling structure 122 to transfer heat to the environment at a greater rate than the first high-power density package 104 or the second high-power density package 124 may transfer heat to the first dielectric fluid 103 or the second dielectric fluid 123.

Additionally, the first cooling structure 102 may include a first vapor collector 101 and the second cooling structure 122 may include a second vapor collector 121. The first vapor collector 101 and the second vapor collector 121 may provide additional passive cooling within the first cooling structure 102 or the second cooling structure 122. The first vapor collector 101 and the second vapor collector 121 may have a generally concave shape oriented towards the first dielectric liquid 106 or the second dielectric liquid 126. At the center of the first vapor collector 101 or the second vapor collector 121 may be a nozzle having a converging-diverging shape. The converging-diverging shaped nozzle of the first vapor collector 101 and the second vapor collector 121 operates using the Venturi effect. The first dielectric vapor 109 or the second dielectric vapor 129 entering the converging-diverging inlet of the first vapor collector 101 or the second vapor collector 121 may transfer a portion of its thermal energy to kinetic energy, as the exhaust velocity is greater than the inlet velocity. As such, the first vapor collector 101 or the second vapor collector 121 may provide passive cooling. Furthermore, a top portion of the first cooling structure 102 may form a first cooling surface 112 while a top portion of the second cooling structure 122 may form a second cooling surface 132. As discussed below, the first cooling surface 112 and the second cooling surface 132 may provide a large surface area for first dielectric vapor 109 or the second dielectric vapor 129 to condense back into droplets of the first dielectric liquid 106 or the second dielectric liquid 126.

In addition, while the examples herein show a first cooling structure 102 and a second cooling structure 122, in other embodiments, the number of cooling structures may be 1, 2, 4, 6, 8, 10, 16, 32, 64, or any other suitable number of cooling structures on a supporting board 110. Each cooling structure may have its own respective high-power density package, as well as dielectric fluids, supporters, connectors, cooling loops, etc.

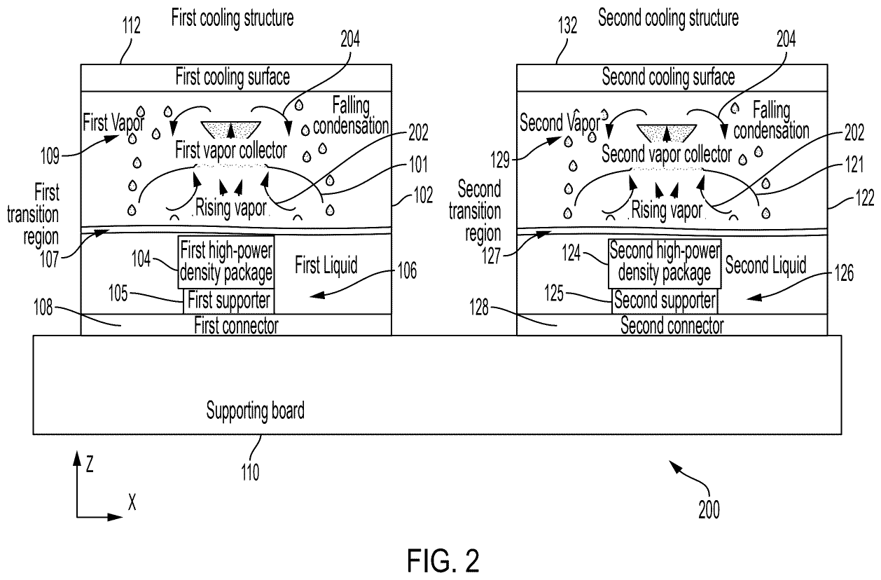

FIG. 2 depicts a more detailed view of the first cooling architecture 100 showing the closed loop cooling 200 of the first cooling structure 102 and the second cooling structure 122 with rising vapor 202 and falling condensation 204. The first vapor collector 101 and the second vapor collector 121 may extend across much of the first cooling structure 102 or the second cooling structure 122 such that rising vapor 202 from the boiling surface of the first transition region 107 or the second transition region 127 may be funneled upwards via the first vapor collector 101 or the second vapor collector 121. As the rising vapor 202 continues to rise, the rising vapor 202 enters the inlet of the converging-diverging region of the first vapor collector 101 or the second vapor collector 121, where the rising vapor 202 converges together towards the middle of the converging-diverging region. At a middle of the converging-diverging region of the first vapor collector 101 or the second vapor collector 121, the nozzle stops converging, and begins to diverge, more gradually than the converging region. As the middle of the converging-diverging region has a smaller diameter than inlet or outlet, fluid passing into the middle of the converging-diverging region has a greater velocity than either the inlet or outlet due to the principle of mass continuity, while Bernoulli's principle causes a drop in pressure such that potential energy including thermal energy may be converted to kinetic energy. Thus, the first vapor collector 101 and the second vapor collector 121 may passively cool the rising vapor 202.

Additionally, the rising vapor 202, after leaving the exhaust of the converging-diverging region of the first vapor collector 101 or the second vapor collector 121, may contact the first cooling surface 112 or the second cooling surface 132, which may have a large surface area and may be cooler than other surfaces of the first cooling structure 102 or the second cooling structure 122. At the first cooling surface 112 or the second cooling surface 132, the rising vapor 202 may condense into liquid droplets and form the falling condensation 204, as the first dielectric fluid 103 or the second dielectric fluid 123 have a phase transition from the first dielectric vapor 109 or the second dielectric vapor 129 back into the first dielectric liquid 106 or the second dielectric liquid 126. The falling condensation 204 may form liquid droplets on the first cooling surface 112 or the second cooling surface 132 until the droplets grow in size large enough to fall on their own back towards the first vapor collector 101 or the second vapor collector 121. In some cases, the first cooling surface 112 may be configured as a nucleation surface and/or the second cooling surface 132 may be configured as a nucleation surface (e.g., a second nucleation surface), As the first vapor collector 101 and the second vapor collector 121 may be formed in a concave shape oriented downwards, the drops of the falling condensation 204 may then drip towards the edge of the first vapor collector 101 or the second vapor collector 121 before falling back into the first dielectric liquid 106 or the second dielectric liquid 126.

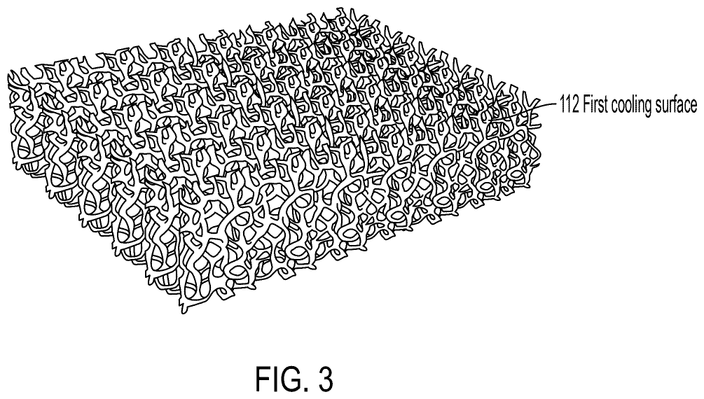

FIG. 3 depicts an example embodiment of the first cooling surface 112, which may be used in the first cooling architecture 100. In the example embodiment, the first cooling surface 112 may be formed of a nanostructured or microstructured material providing a large surface area. For example, the first cooling surface 112 may be from a material such as a copper foam, whose surface forms a series of cells with open pores, as well as other suitable materials including aluminum foam or dope carbon foams, or any other suitable material. The open pores of each cell may provide a large number of openings, greatly extending the available surface area for the rising vapor 202 to contact the first cooling surface 112. Additionally, the open pores may act as nucleation sites for the rising vapor 202 to condense into the falling condensation 204. The second cooling surface 132 may be formed similarly to the first cooling surface 112.

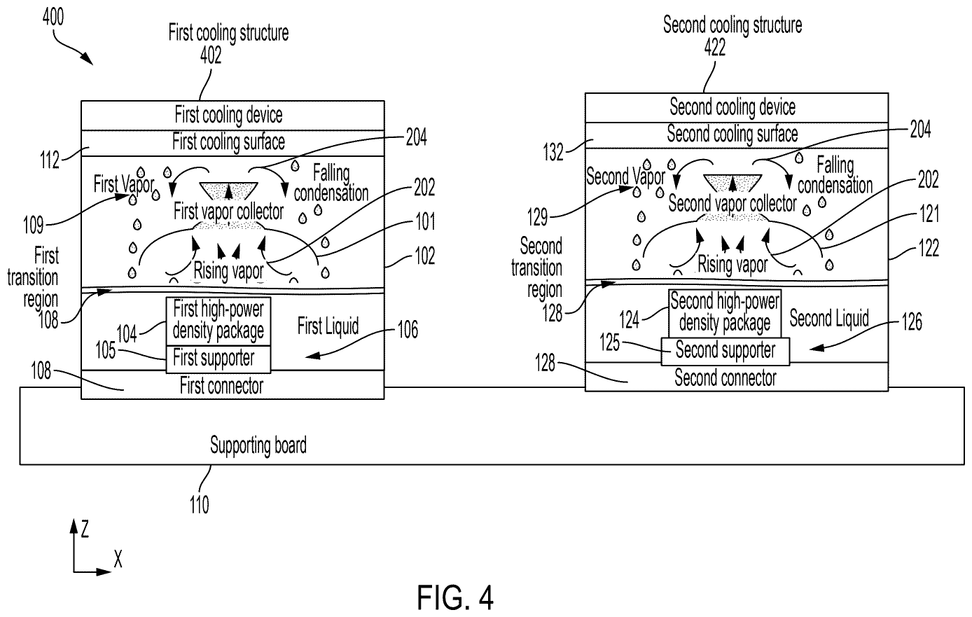

FIG. 4 depicts an example of a second cooling architecture 400, differing from the first cooling architecture 100 by adding a first cooling device 402 to the first cooling structure 102 and a second cooling device 422 to the second cooling structure 122. The first cooling device 402 and the second cooling device 422 may take the form of any suitable active cooling device, such as a thermoelectric cooler, a cold plate, a heat exchanger, a fan, as well as passive cooling devices such as radiating fins, as well as combinations thereof. Such a listing of elements is not intended to be exhaustive, and in other embodiments, any known type of cooling device may be used either alone or in combination. In some embodiments, the first cooling device 402 and the second cooling device 422 may be mounted on a top surface of the first cooling structure 102 or the second cooling structure 122 on a side of the opposite the first cooling surface 112 or the second cooling surface 132. In some embodiments, the first cooling device 402 and the second cooling device 422 may include multiple cooling devices which may be mounted on the top, bottom or sidewalls of the first cooling structure 102 or the second cooling structure 122. As the first cooling structure 102 and the second cooling structure 122 may be sealed to form a closed loop, the first cooling device 402 and the second cooling device 422 may transfer heat from the surface of the first cooling structure 102 or the second cooling structure 122 without directly contacting the first dielectric fluid 103 or the second dielectric fluid 123. The first cooling device 402 and the second cooling device 422 may in turn be fluidically coupled to additional cooling devices, for example, when the first cooling device 402 and the second cooling device 422 are cold plates, the cold plates may circulate fluid which may be pumped to additional heat exchangers to cool the fluid. The first cooling device 402 and the second cooling device 422 may provide additional cooling to the passive heat exchange between the first cooling structure 102 or the second cooling structure 122 and the ambient environment. The additional cooling may help maintain the first dielectric fluid 103 or the second dielectric fluid 123 in a desired temperature range, and thus the first high-power density package 104 or the second high-power density package 124 within a desired operating temperature range.

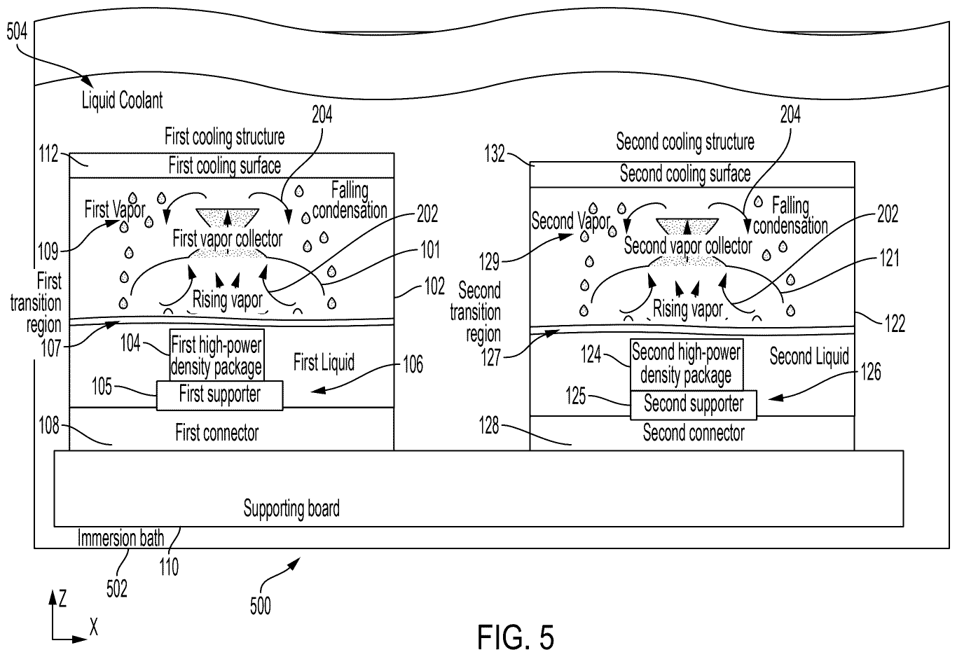

FIG. 5 depicts a third cooling architecture 500, differing from the first cooling architecture 100 by placing the first cooling architecture 100 including the supporting board 110 and both the first cooling structure 102 and the second cooling structure 122 into an immersion bath 502. The immersion bath 502 may contain a liquid coolant 504, which may be a liquid dielectric, such as the first dielectric fluid 103 or the second dielectric fluid 123. In the example of FIG. 1, both the first cooling structure 102 and the second cooling structure 122 are shown as submerged with the liquid coolant 504 including the top surface. As such, heat conducted by the first high-power density package 104 or the second high-power density package 124 to the first dielectric fluid 103 or the second dielectric fluid 123 may be conducted via the top and sides of the first cooling structure 102 or the second cooling structure 122 to the liquid coolant 504. However, the difference in sizes between the immersion bath 502 and the first cooling structure 102 or the second cooling structure 122, as well as the nature of the first cooling structure 102 and the second cooling structure 122 being sealed allows different materials to be used. The first dielectric fluid 103 and the second dielectric fluid 123, as being sealed within a small volume, may have their material chosen based on the boiling point of the fluid. The relatively small volume allows for a more expensive but more efficient fluid to be used within the first cooling structure 102 or the second cooling structure 122 as they may be closed cycles and sealed. In addition, the smaller and sealed volume allows for dielectric materials such as fluorinated liquids, which may have corrosive or reactive properties that may be undesirable for larger immersion baths, where the larger immersion baths may require additional servicing. In addition, the first cooling structure 102 and the second cooling structure 122 may resolve potential issues from placing high-power density packages directly into an immersion bath, as the first cooling structure 102 and the second cooling structure 122 passively transfer heat in a closed cycle away from the first high-power density package 104 or the second high-power density package 124. Placing a high-power density package directly into a larger immersion bath may risk the heat from a high-power density package may not be transferred sufficiently fast enough to keep the high-power density package operating due to the smaller surface area of the high-power density package in comparison to the first cooling structure 102 or the second cooling structure 122.

In the example of FIG. 5, the immersion bath 502 is shown as an open bath, but in other embodiments, the immersion bath 502 may be a closed bath. Additionally, in the example of FIG. 5, the immersion bath 502 is shown has only holding the supporting board 110 and its components, but in other embodiments, the immersion bath 502 may contain additional portions of a computing environment, such as an entire computer, server, server rack, and/or datacenter within the same immersion bath. In some embodiments, the immersion baths may be nested, for example, one or more high-power density packages may be mounted in individual cooling structures on the supporting board 110. The supporting board 110 may then itself be placed within a larger board immersion cooling structure containing the board and individual cooling structures. Multiple boards, each within an individual board immersion cooling structure, may be placed within a server cooling structure intended to cool an entire server. Multiple server cooling structures may be then placed within a server rack cooling structure. Finally, a datacenter may have an open immersion cooling bath where multiple server racks may be cooled. A given server rack (e.g., each server rack) may include one or more cooling structures.

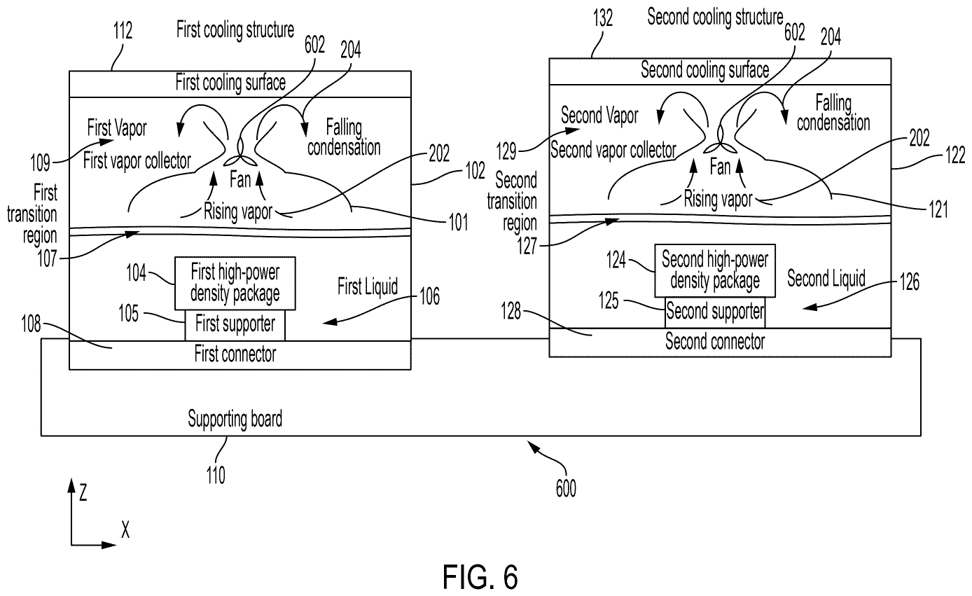

FIG. 6 depicts a fourth cooling architecture 600, differing from the first cooling architecture 100 by including fans 602 to provide forced gas flow via the first vapor collector 101 or the second vapor collector 121. The fans 602 may be used to accelerate the rising vapor 202 before entering the converging-diverging shaped region of the first vapor collector 101 or the second vapor collector 121, causing an increase to the flow rate, which at the middle portion of the converging-diverging shaped region causes a further increase to the velocity of the rising vapor 202, and thus further cool the rising vapor 202. In some embodiments, fans 602 may be used intermittently, for example to provide an initial flow of gas via the converging-diverging nozzle to start the closed loop cooling cycle, as well as may be used to provide additional cooling based on the temperature of a high-power density package exceeding a threshold.

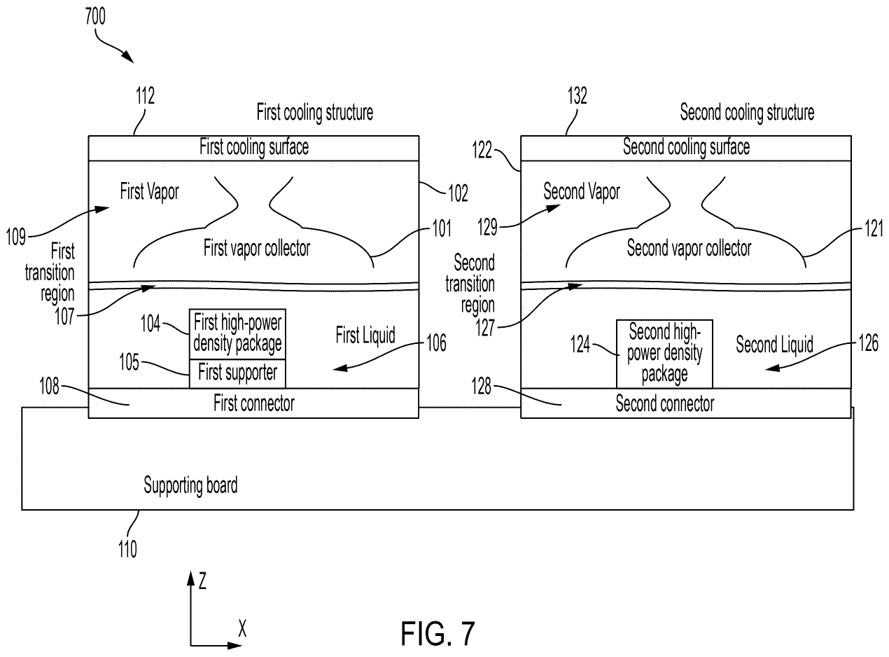

FIG. 7 depicts an example of a fifth cooling architecture 700, differing from the first cooling architecture 100 by presenting a version of the second cooling structure 122 without the second supporter 125. While the first cooling architecture 100 provides each cooling structure shown with an individual supporter to couple the high-power density package to the supporting board 110, in some embodiments, such as FIG. 7, the supporters may be omitted, such that the second high-power density package 124 may directly rest on a bottom surface of the second cooling structure 122.

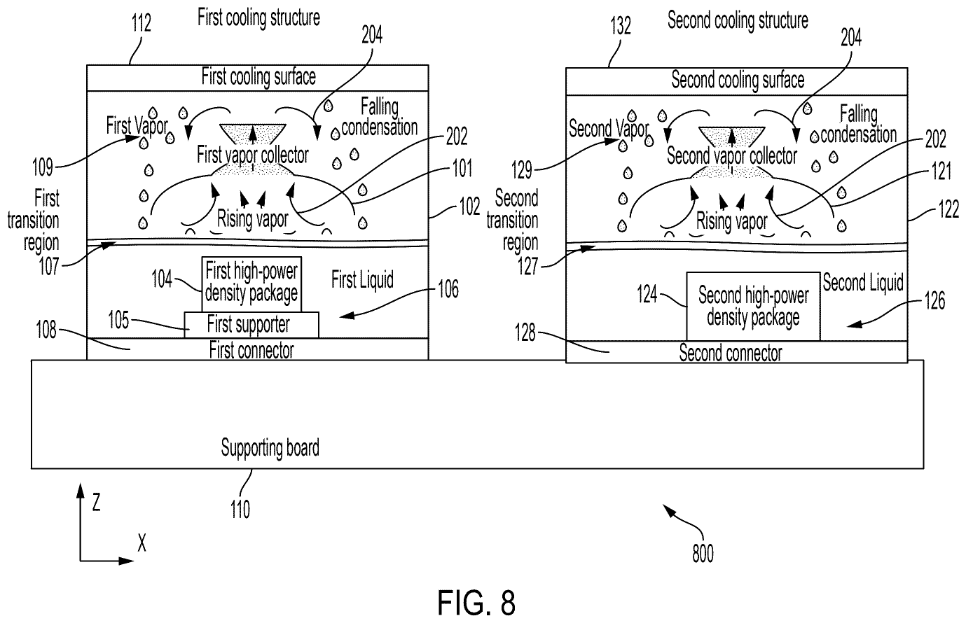

FIG. 8 depicts a more detailed view of the fifth cooling architecture 700 showing the closed loop cooling 800 of the first cooling structure 102 and the second cooling structure 122 with rising vapor 202 and falling condensation 204 when using an example of the fifth cooling architecture 700 where the second high-power density package 124 may directly rest on a bottom surface of the second cooling structure 122.

In some embodiments, supporters may be completely omitted such that all high-power density packages may rest on the bottom surfaces of their respective cooling structures, while in other embodiments, a mix of direct resting and supporter resting high-power density packages may be used. The high-power density packages may, in some embodiments, be coupled directly via the bottom of their cooling structure to the supporting board 110 to provide a shorter direct connection to reduce latency and increase throughput of signals to and from the high-power density packages, while in other embodiments a supporter may be used, for example, to provide additional surface area to cool the high-power density packages.

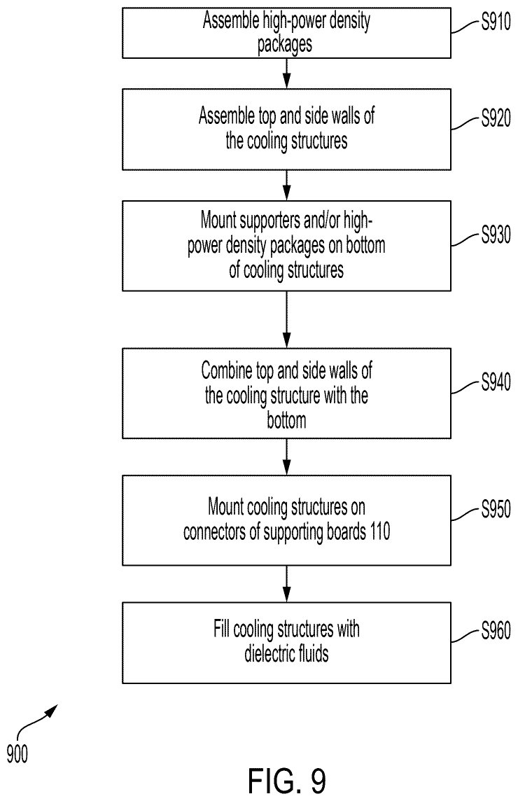

FIG. 9 depicts an example embodiment of a process 900 for assembling a cooling architecture such as the first cooling architecture 100 or any other cooling architectures shown in FIGS. 1-8.

In the process 900 at S910, the high-power density packages, including the first high-power density package 104 and the second high-power density package 124 are assembled. The high-power density packages may be assembled in a front end of line (FEOL) or back end of line (BEOL) facility, as well as a combination thereof. The high-power density packages may be assembled from one or more integrated circuits including processing units, memory units, logic circuity, power conditioning circuitry, and may include CPUs, XPUs, GPUs, NPUs, advanced packages such as HBM, as well as three-dimensional structures such device stacks, VSDRAM or any other suitable package. In some embodiments, the high-power density package may include photonic devices such as planar lightwave circuits (PLCs) either alone or in combination with other forms of integrated circuits. The high-power density packages may be mounted on one or more shared substrates such as silicon, silicon on insulator, glass, germanium, as well as organic substrates. In some embodiments, the high-power density packages may be mounted on one or more interposers. The devices in the high-power density packages may be mounted using various techniques including a conductive connection such as pads, bumps, microbumps, pillars, balls, ball grids, microball arrays, and other forms such as controlled-collapse chip connection (C4) bumps, alone or in combination. As used herein, a C4 bump refers to a form of solder bumps placed on pads on a top surface of a substrate prior to flipping the substrate to form a flip-chip. The mounting method may further include a dielectric material, which may include a material such as an adhesive, resin, or elastomer which may form a connection in addition to a conductive connection and may be provided using an underfill method. In some embodiments, the devices of the high-power density packages may be further secured using an epoxy molding compound (EMC) or other suitable techniques to encapsulate the high-power density packages.

In the process 900 at S920, the cooling structures such as the first cooling structure 102 and the second cooling structure 122 have the top and side walls assembled. The top and side walls of the cooling structures may be assembled using various techniques including mechanical connections, molding, welding, brazing, soldering, additive manufacturing, spinning, weaving, or any other suitable method with the techniques varying on the materials of the cooling structures. In some embodiments, sealing elements such as gaskets, washers, etc. may be used to provide a tighter fit between each component.

The cooling surfaces such as the first cooling surface 112 and the second cooling surface 132, in some embodiments may be formed as a portion of the top of the cooling structure prior to assembly with the side walls. In some embodiments, the cooling surfaces may extend such that the entire top of the cooling structure may be formed from the cooling surface. In other embodiments, the cooling surfaces may be mounted or formed on the top surface either before or after the top is assembled with the side walls. The cooling surfaces may be formed from a boiling enhancement material, such as heat conductive open cell foam like copper foam as well as silicon carbide foam other microporous structures such as doped carbon filaments. The cooling surfaces may, in some embodiments, be formed directly on the top of the cooling structure, for example via electroplating, deposition, spinning, additive manufacturing techniques or any other suitable technique. In some embodiments, the cooling surfaces may be formed separately and joined to the top surface of the cooling structure using various techniques such as welding, brazing, soldering, adhesives, mechanical connections, or other suitable techniques.

The vapor collectors, such as the first vapor collector 101 and the second vapor collector 121, may be formed separately from the top and side walls of the cooling structures, and coupled to the top and side walls of the cooling structure during assembly. The vapor collectors may be held in place such as via one or more supporting structures such as struts, cables, protrusions from the top or side walls, or any other suitable method. The vapor collectors may be held in place using various techniques including mechanical connections, molding, welding, brazing, soldering, as well as adhesives and molding compounds or any other suitable method. In some embodiments, where a fan or other active element may be placed within the vapor collector, those elements may be assembled with the vapor collector prior to or after the vapor collector is coupled to the top or side walls of the cooling structures.

In the process 900 at S930, supporters such as the first supporter 105 or the second supporter 125 may be mounted on bottom surface of the cooling structures. In some embodiments, the high-power density packages may be mounted on a supporter either prior to or after the supporters are mounted on the bottom surface of the cooling structures. In some embodiments, the supporters may be omitted and the high-power density packages may be directly mounted on the bottom of the cooling structure. The bottom of the cooling structures may include one or more holes, vias, slots, or other pathways to allow power and communications signals to travel to the high-power density packages. In some embodiments, the supporter may directly contact the connectors on the supporting board 110 by extending through a portion of the bottom surface of the cooling structures. The supporters and high-power density packages may be mounted using various techniques including a conductive connection such as pads, bumps, microbumps, pillars, balls, ball grids, microball arrays, and other forms such as C4 bumps, or any other suitable method alone or in combination. The mounting method may further include a dielectric material, which may include a material such as an adhesive, resin, or elastomer which may form a connection in addition to a conductive connection and may be provided using an underfill method.

In the process 900 at S940, the top and side walls of the cooling structures are combined with the bottom surfaces to form a completed cooling structure. The top, side walls and bottom surfaces may be assembled using various techniques including mechanical connections, molding, welding, brazing, soldering, additive manufacturing, spinning, weaving, or any other suitable method with the techniques varying on the materials of the cooling structures. In some embodiments, sealing elements such as gaskets, washers, etc. may be used to provide a tighter fit between each component.

In the process 900 at S950, the cooling structures are mounted on the connectors of the supporting board 110, such as the first connector 108 or the second connector 128. In some embodiments, the high-power density packages may be directly coupled to the connectors while in other embodiments one or more intermediate structures such as the supporters may be between the high-power density packages and the connectors of the supporting board 110. The cooling structures and the high-power density packages along with any intermediate structures may be mounted to the connectors using various techniques including a conductive connection such as pads, bumps, microbumps, pillars, balls, ball grids, microball arrays, and other forms such as C4 bumps, or any other suitable method alone or in combination. The connecting method may further include a dielectric material, which may include a material such as an adhesive, resin, or elastomer which may form a connection in addition to a conductive connection and may be provided using an underfill method.

In the process 900 at S960, the cooling structures may be filled with the dielectric fluids such as the first dielectric fluid 103 or the second dielectric fluid 123. The dielectric fluids may be provided, for example, via an formed on side of the cooling structure. The dielectric fluid may be filled so as to fully immerse the high-power density packages within the fluid and may include sufficient dielectric fluid in the liquid phase such that the high-power density packages are fully immersed in liquid. In some embodiments, head space may remain above the high-power density packages such that vapor or gas may remain within the cooling structure. The dielectric fluid may be such that at room temperature the dielectric fluid has a liquid phase present in sufficient volume to immerse the high-power density packages, but the liquid phase is below the height of the vapor collector.

While this specification may contain many specific implementation details, the implementation details should not be construed as limitations on the scope of any claimed subject matter but rather be construed as descriptions of features specific to particular embodiments. Certain features that are described in this specification in the context of separate embodiments may also be implemented in combination in a single embodiment. Conversely, various features that are described in the context of a single embodiment may also be implemented in multiple embodiments separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described herein. Other embodiments are within the scope of the following claims. In some cases, the actions set forth in the claims may be performed in a different order and still achieve desirable results. Additionally, the processes depicted in the accompanying figures do not necessarily require the particular order shown, or sequential order, to achieve desirable results. In certain implementations, multitasking and parallel processing may be advantageous.

As will be recognized by those skilled in the art, the innovative concepts described herein may be modified and varied over a wide range of applications. Accordingly, the scope of claimed subject matter should not be limited to any of the specific example teachings discussed above, but is instead defined by the following claims.

What is claimed is:

1. A device comprising:
a supporting board; and
a first cooling structure on the supporting board, the first cooling structure including:
a first high-power density package immersed within a first dielectric fluid, the first dielectric fluid thermally coupled to the first high-power density package, the first high-power density package communicatively coupled to the supporting board, and
a first vapor collector having a converging-diverging shape within the first cooling structure,
wherein the first dielectric fluid circulates in a closed loop within the first cooling structure.

2. The device of claim 1, wherein the first dielectric fluid has a first liquid phase and a first vapor phase within the first cooling structure,
and wherein the first dielectric fluid circulating in the closed loop within the first cooling structure includes the first liquid phase transitioning to the first vapor phase and the first vapor phase transitioning to the first liquid phase.

3. The device of claim 1, further comprising:
a second cooling structure on the supporting board, the second cooling structure including:
a second high-power density package immersed within a second dielectric fluid, the second dielectric fluid thermally coupled to the second high-power density package, the second high-power density package communicatively coupled to the supporting board; and
a second vapor collector having a converging-diverging shape within the second cooling structure.

4. The device of claim 1, wherein the first high-power density package includes at least one selected from the group consisting of a memory device and a processing device.

5. The device of claim 1, wherein the first cooling structure has a fixed volume that the first dielectric fluid circulates within.

6. The device of claim 1, wherein the first dielectric fluid passively circulates in the closed loop within the first cooling structure.

7. The device of claim 1, wherein the first vapor collector includes a fan to actively circulate the first dielectric fluid in the closed loop within the first cooling structure.

8. A device comprising:
a supporting board; and
a first cooling structure on the supporting board, the first cooling structure including:
a first high-power density package immersed within a first dielectric fluid, the first dielectric fluid thermally coupled to the first high-power density package, the first high-power density package communicatively coupled to the supporting board,
a first vapor collector having a converging-diverging shape within the first cooling structure, the first vapor collector passively circulating the first dielectric fluid, and
the first cooling structure providing a nucleation site for the first dielectric fluid to transition from vapor phase to liquid phase.

9. The device of claim 8, wherein the first cooling structure has a fixed volume, and
wherein the first dielectric fluid circulates in a closed loop within the first cooling structure.

10. The device of claim 8, wherein at least one cooling device is mounted on an exterior of the first cooling structure, and
wherein at least one cooling device includes one or more of a thermoelectric cooler, a cold plate, a heat exchanger, a radiative fin, and a heat sink.

11. The device of claim 8, wherein the first high-power density package includes at least one selected from the group consisting of a memory device and a processing device.

12. The device of claim 8, further comprising:
a second cooling structure on the supporting board, the second cooling structure including:
a second high-power density package immersed within a second dielectric fluid, the second dielectric fluid thermally coupled to the second high-power density package, the second high-power density package communicatively coupled to the supporting board,
a second vapor collector having a converging-diverging shape within the second cooling structure, the second vapor collector passively circulating the second dielectric fluid, and
the second cooling structure providing a nucleation site for the second dielectric fluid to transition from vapor phase to liquid phase.

13. The device of claim 8, wherein the first vapor collector includes a fan to actively circulate the first dielectric fluid in a closed loop within the first cooling structure.

14. A system comprising:
a supporting board;
a first cooling structure on the supporting board, the first cooling structure including:
a first high-power density package immersed within a first dielectric fluid, the first dielectric fluid thermally coupled to the first high-power density package, the first high-power density package communicatively coupled to the supporting board, and
a first vapor collector having a converging-diverging shape within the first cooling structure; and
a second cooling structure on the supporting board, the second cooling structure including:
a second high-power density package immersed within a second dielectric fluid, the second dielectric fluid thermally coupled to the second high-power density package, the second high-power density package communicatively coupled to the supporting board, and
a second vapor collector having a converging-diverging shape within the second cooling structure,
wherein the first vapor collector passively circulates the first dielectric fluid and the second vapor collector passively circulates the second dielectric fluid.

15. The system of claim 14, wherein the first high-power density package includes at least one selected from the group consisting of a memory device and a processing device.

16. The system of claim 14, wherein the supporting board, the first cooling structure, and the second cooling structure are immersed within a liquid coolant in an immersion bath.

17. The system of claim 14, wherein:
the first cooling structure has a first boiling enhancement surface providing a first nucleation site for the first dielectric fluid to condense; and
the second cooling structure has a second boiling enhancement surface providing a second nucleation site for the second dielectric fluid to condense.

18. The system of claim 14, wherein the first vapor collector includes a first fan to actively circulate the first dielectric fluid in a closed loop within the first cooling structure, and
wherein the second vapor collector includes a second fan to actively circulate the second dielectric fluid in a closed loop within the second cooling structure.

19. The system of claim 14, wherein:
at least one first cooling device is mounted on an exterior of the first cooling structure, and the at least one first cooling device includes one or more of a thermoelectric cooler, a cold plate, a heat exchanger, a radiative fin, and a heat sink; and
at least one second cooling device is mounted on an exterior of the second cooling structure, and the at least one second cooling device includes one or more of a thermoelectric cooler, a cold plate, a heat exchanger, a radiative fin, and a heat sink.

20. The system of claim 14, wherein:
the first cooling structure has a fixed volume, and
the second cooling structure has a fixed volume.
